(19) United States
(12) Patent Application Publication
(10) Pub. No.: US 2019/0074173 A1
(43) Pub. Date: Mar. 7, 2019

(54) Water-Repellent Protective Film Forming Agent, Liquid Chemical for Forming Water-Repellent Protective Film, and Wafer Cleaning Method

(71) Applicant: Central Glass Company, Limited, Ube-shi, Yamaguchi (JP)

(72) Inventors: Yuki FUKUI, Ube-shi, Yamaguchi (JP); Takashi SAIO, Toyonaka-shi, Osaka (JP); Atsushi RYOKAWA, Ube-shi, Yamaguchi (JP); Satoru NARIZUKA, Ube-shi, Yamaguchi (JP); Saori SHIOTA, Ube-shi, Yamaguchi (JP); Shota WATANABE, Ube-shi, Yamaguchi (JP); Shintaro SASAKI, Ube-shi, Yamaguchi (JP); Susumu IWASAKI, Ube-shi, Yamaguchi (JP)

(21) Appl. No.: 16/084,697

(22) PCT Filed: Mar. 7, 2017
(86) PCT No.: PCT/JP2017/008910

§ 371 Date: Sep. 13, 2018

(30) Foreign Application Priority Data
Mar. 15, 2016 (JP) 2016-050763

(51) Int. Cl. H01L 21/02; C09D 5/00; C07F 7/10

(52) U.S. Cl. CPC H01L 21/02057; C07F 7/10; C09D 5/00

(57) ABSTRACT

Disclosed are a water-repellent protective film forming agent for forming a water-repellent protective film on a silicon element-containing surface of a wafer and a water-repellent protective film forming liquid chemical in which the water-repellent protective film forming agent is dissolved in an organic solvent, characterized in that the water-repellent protective film forming agent consists of at least one kind of silicon compound selected from the group consisting of a sulfonimide derivative represented by the following general formula [1], a sulfonimide derivative represented by the following general formula [2] and a sulfonmethide derivative represented by the following general formula [3].

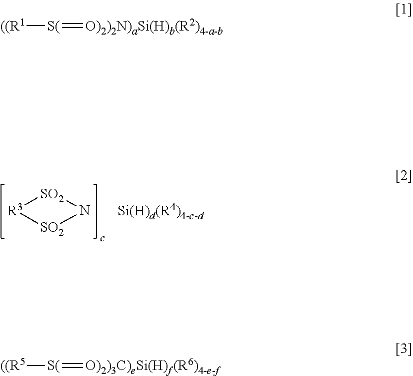

### FIELD OF THE INVENTION

The present invention relates to a water-repellent protective film forming agent for forming a water-repellent protective film on a surface of a wafer and to a water-repellent protective film forming liquid chemical.

### BACKGROUND ART

It is required that semiconductor devices for network applications and digital home appliances have higher performance, higher functionality and lower power consumption. The fine processing of circuit patterns has accordingly been pursued. With the fine processing of circuit patterns, however, pattern collapses are becoming a problem. The manufacturing of the semiconductor device makes great use of a cleaning process to remove particles and metal impurities. Eventually, the cleaning process occupies 30 to 40% of the entire semiconductor manufacturing process. The pattern collapse is a phenomenon in which the pattern collapses due to the passage of a gas-liquid interface through the pattern after washing or rinsing in the cleaning process when the aspect ratio of the pattern becomes high with the fine patterning of the semiconductor device. The design of the pattern has to be changed in order to prevent a pattern collapse. Further, the occurrence of a pattern collapse leads to a deterioration in manufacturing yield. It is thus demanded to develop a technique for preventing a pattern collapse in the cleaning process.

The formation of a water-repellent protective film on a surface of the pattern is known as an effective technique for preventing a pattern collapse. It is necessary to perform such water repelling treatment without drying the surface of the pattern. The water-repellent protective film is hence formed using a water-repellent protective film forming liquid chemical to impart water repellency to the surface of the pattern.

The present applicant has disclosed in Patent Document 1 a silicon wafer cleaning agent used, in a method of producing a silicon wafer having on a surface thereof a fine uneven pattern, for improving a cleaning process in which a pattern collapse is likely to be induced. This silicon wafer cleaning agent is characterized by containing at least an aqueous cleaning liquid and a water-repellent cleaning liquid for imparting water repellency to at least recess portions of the uneven pattern during the cleaning process, wherein the water-repellent cleaning liquid is a water-repellent compound having a reactive moiety chemically bondable to Si of the silicon wafer as well as a hydrophobic group, or a mixture containing 0.1 mass % or more of the water-repellent compound in an organic solvent based on 100 mass % of the total amount of the water-repellent cleaning liquid; wherein, assuming that water is retained in the recess portions of the silicon wafer surface on which water repelling treatment has been performed by the water-repellent cleaning liquid, the capillary force is 2.1 MN/m² or smaller; and wherein the water-repellent compound is at least one selected from the group consisting of compounds represented by the following general formulas [A], [B] and [C]. Also disclosed is a wafer cleaning method using such a silicon wafer cleaning agent.

(R¹)ₐSi(CH₃)_{b}H_{c}X_{4-a-b-c} [A]

R²Si(CH₃)_{2-d}H_{d})ₑNH₃₋ₑ [B]

R³Si(CH₃)₂Y [C]

In the formulas [A], [B] and [C], R² and R³ are each independently a monovalent C₁-C₁₈ hydrocarbon-containing organic group or a monovalent C₁-C₈ fluoroalkyl chain-containing organic group; X is a chloro group, an isocyanate group or an alkoxy group; Y is a monovalent organic group whose element to be bonded to Si is nitrogen; a is an integer of 1 to 3; each of b and c is an integer of 0 to 2; the sum of a, b and c is 1 to 3; d is an integer of 0 to 2; and e is an integer of 1 to 3.

Further, the present applicant has disclosed in Patent Document 2 a protective film forming liquid chemical used, in a method of producing a wafer having on a surface thereof a fine uneven pattern which at least partially contains silicon element, for forming a water-repellent protective film on the uneven pattern of the wafer so as to improve a cleaning process in which a pattern collapse is likely to be induced without causing a deterioration in throughput. More specifically, this protective film forming liquid chemical is used, in a process of cleaning a wafer having on a surface thereof a fine uneven pattern which at least partially contains silicon element, for forming a water-repellent protective film on at least surfaces of recess portions of the uneven pattern, and is characterized by containing: a silicon compound A represented by the following general formula [D]: and an acid capable of donating a proton to the silicon compound A and/or an acid capable of accepting an electron from the silicon compound A, wherein the total amount of water in the starting raw materials of the liquid chemical is 5000 mass ppm or less relative to the total amount of the raw materials. Also disclosed is a wafer cleaning method using such a protective film forming liquid chemical.

R⁴_{f}Si(H)_{g}(Z)_{4-f-g} [D]

In the formula [D], R⁴ is each independently at least one group selected from monovalent C₁-C₁₈ hydrocarbon-containing organic groups and monovalent C₁-C₈ fluoroalkyl chain-containing organic groups; Z is each independently at least one group selected from halogen groups, monovalent organic groups in which elements bonded to Si are oxygen or nitrogen, and nitrile group; f is an integer of 1 to 3; g is an integer of 0 to 2; and the sum off and g is 3 or smaller.

### PRIOR ART DOCUMENTS

### Patent Documents

Patent Document 1: Japanese Laid-Open Patent Publication No. 2010-192878

Patent Document 2: Japanese Laid-Open Patent Publication No. 2012-033873

### SUMMARY OF THE INVENTION

### Problems to be Solved by the Invention

The combinations of material and film configurations of semiconductor wafers are infinitely increasing with improvement in the performance and functionality of devices. In the case of wafers having surfaces containing silicon element, circuit patterns are formed from various materials including not only silicon-containing layers but also metal wiring layers, electrode layers, capacitor layers, dielectric layers, device forming layers and the like.

Under the above-mentioned circumstance where the combinations of configurations of semiconductor wafers are still infinitely increasing, it is desired to ensure as many options of novel water-repellent protective film forming liquid chemicals as possible, in addition to conventional water-repellent protective film forming liquid chemicals, whereby suitable liquid chemicals can be applied to form water-repellent protective films on wafer surfaces and prevent pattern collapses during cleaning process.

Further, there is a possibility that, depending on the wafer configuration, the wafer may be adversely affected by a component of the water-repellent protective film forming liquid chemical. In the case of using a silane such as chlorosilane, bromosilane or iodosilane, for example, the wafer may be affected by a chlorine atom, bromine atom or iodine atom of the silane depending on the wafer configuration. The water-repellent cleaning liquid of Patent Document 1 is capable of imparting high water repellency to a surface of a silicon wafer. When the water-repellent cleaning liquid contains a chlorosilane compound as the water-repellent compound as in Example 22 of Patent Document 1, however, the wafer may be adversely affected by a chorine atom depending on the wafer configuration. There are cases where it is desirable for the water-repellent protective film forming component to contain no chlorine atom.

The protective film forming liquid chemical of Patent Document 2 is capable of imparting high water repellency to a silicon element-containing surface of a wafer, but needs to be prepared by respectively accurately weighing the silicon compound A as the protective film forming component and the acid as the protective film formation promoting component and controlling the concentrations of these components. In terms of loads of liquid chemical preparation and concentration control, it is desirable to provide a water-repellent protective film forming liquid chemical that does not require a protective film formation promoting component as an essential component.

In view of the foregoing, it is an object of the present invention to provide a novel water-repellent protective film forming agent (hereinafter sometimes simply referred to as “protective film forming agent” or “agent”) or novel water-repellent protective film forming liquid chemical (hereinafter sometimes simply referred to as “protective film forming liquid chemical” or “liquid chemical”) capable of forming a water-repellent protective film on a silicon element-containing surface of a wafer, with no choline atom being contained in a water-repellent protective film forming component thereof and without the need to use a protective film formation promoting component as an essential component. It is also an object of the present invention to provide a method for cleaning a wafer with the use of such an agent or liquid chemical.

### Means for Solving the Problems

The present invention provides a water-repellent protective film forming agent for forming a water-repellent protective film on a silicon element-containing surface of a wafer, consisting of at least one kind of silicon compound selected from the group consisting of a sulfonimide derivative represented by the following general formula [1], a sulfonimide derivative represented by the following general formula [2] and a sulfonmethide derivative represented by the following general formula [3]

((R¹—S(═O)₂)₂N)ₐSi(H)_{b}(R²)_{4-a-b} [1]

where R¹ is each independently a group selected from the group consisting of a C₁-C₈ monovalent hydrocarbon group in which a part or all of hydrogen elements may be substituted with a fluorine elements, and a fluorine element; R² is each independently a C₁-C₁₈ monovalent hydrocarbon group in which a part or all of hydrogen elements may be substituted with a fluorine element; a is an integer of 1 to 3; b is an integer of 0 to 2; and the sum of a and b is 3 or smaller,

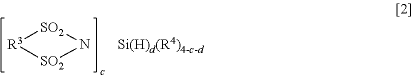

where R³ is each independently a C₁-C₈ divalent hydrocarbon group in which a part or all of hydrogen elements may be substituted with a fluorine element; R⁴ is each independently a C₁-C₁₈ monovalent hydrocarbon group in which a part or all of hydrogen elements may be substituted with a fluorine element; c is an integer of 1 to 3; d is an integer of 0 to 2; and the sum of c and d is 3 or smaller,

((R⁵—S(═O)₂)₃C)ₑSi(H)_{f}(R⁶)_{4-e-f} [3]

where R⁵ is each independently a group selected from the group consisting of a C₁-C₈ monovalent hydrocarbon group in which a part or all of hydrogen elements may be substituted with a fluorine element, and a fluorine element; R⁶ is each independently a C₁-C₁₈ monovalent hydrocarbon group in which a part or all of hydrogen elements may be substituted with a fluorine element; e is an integer of 1 to 3; f is an integer of 0 to 2; and the sum of e and f is 3 or smaller.

In the above general formula [1], it is preferable that: a is 1; and b is 0.

In the above general formula [2], it is preferable that: c is 1; and d is 0.

In the above general formula [3], it is preferable that: e is 1; and f is 0.

In the above general formula [1], it is preferable that at least two of R² are methyl.

In the above general formula [2], it is preferable that at least two of R⁴ are methyl.

In the above general formula [3], it is preferable that at least two of R⁶ are methyl.

The present invention also provides a water-repellent protective film forming liquid chemical comprising: an organic solvent; and the above-mentioned water-repellent protective film forming agent dissolved in the organic solvent.

It is preferable that the concentration of the water-repellent protective film forming agent is 0.01 to 25 mass % based on 100 mass % of the total amount of the water-repellent protective film forming agent and the organic solvent.

It is preferable that the organic solvent is an aprotic solvent.

It is preferable that the total amount of water contained in the water-repellent protective film forming agent and the organic solvent before preparation of the water-repellent protective film forming liquid chemical is 5000 mass ppm or less relative to the total amount of the water-repellent protective film forming agent and the organic solvent.

The present invention further provides a method for cleaning a silicon element-containing surface of a wafer with the use of the above-mentioned water-repellent protective film forming agent or water-repellent protective film forming liquid chemical.

The water-repellent protective film forming agent or water-repellent protective film forming liquid chemical of the present invention is capable of forming a water-repellent protective film on a silicon element-containing surface of a wafer so as to lower the capillary force on the unevenly patterned surface of the wafer and exert a pattern collapse preventing effect. Thus, the water-repellent protective film forming agent or water-repellent protective film forming liquid chemical of the present invention ensures a new option for use in still increasing, infinite combinations of semiconductor wafer configurations.

### BRIEF DESCRIPTION OF DRAWINGS

FIG. 1 is a schematic perspective view of a wafer 1 having on a surface thereof a fine uneven pattern 2.

FIG. 2 is a view showing a part of a-a′ cross section of FIG. 1.

FIG. 3 is a schematic view showing a state where a liquid water-repellent protective film forming agent or protective film forming liquid chemical 8 is retained in recess portions 4 of the pattern during cleaning process.

FIG. 4 is a schematic view showing a state where a liquid is retained in the recess portions 4 on which a protective film has been formed.

### DETAILED DESCRIPTION OF EMBODIMENTS

1. Water-Repellent Protective Film Forming Agent and Water-Repellent Protective Film Forming Liquid Chemical

The water-repellent protective film forming agent according to the present invention consists of at least one kind of silicon compound selected from the group consisting of a sulfonimide derivative represented by the following general formula [1], a sulfonimide derivative represented by the following general formula [2] and a sulfonmethide derivative represented by the following general formula [3].

((R¹—S(═O)₂)₂N)ₐSi(H)_{b}(R²)_{4-a-b} [1]

In the general formula [1], R¹ is each independently a group selected from the group consisting of a C₁-C₈ monovalent hydrocarbon group in which a part or all of hydrogen elements may be substituted with a fluorine element, and a fluorine element; R² is each independently a C₁-C₁₈ monovalent hydrocarbon group in which a part or all of hydrogen elements may be substituted with a fluorine element; a is an integer of 1 to 3; b is an integer of 0 to 2; and the sum of a and b is 3 or smaller.

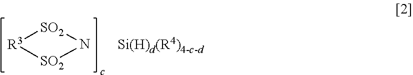

In the general formula [2], R³ is each independently a C₁-C₈ divalent hydrocarbon group in which a part or all of hydrogen elements may be substituted with a fluorine element; R⁴ is each independently a C₁-C₁₈ monovalent hydrocarbon group in which a part or all of hydrogen elements may be substituted with a fluorine element; c is an integer of 1 to 3; d is an integer of 0 to 2; and the sum of c and d is 3 or smaller.

((R⁵—S(═O)₂)₃C)ₑSi(H)_{f}(R⁶)_{4-e-f} [3]

In the general formula [3], R⁵ is each independently a group selected from the group consisting of a C₁-C₈ monovalent hydrocarbon group in which a part or all of hydrogen elements may be substituted with a fluorine element, and a fluorine element; R⁶ is each independently a C₁-C₁₈ monovalent hydrocarbon group in which a part or all of hydrogen elements may be substituted with a fluorine element; e is an integer of 1 to 3; f is an integer of 0 to 2; and the sum of e and f is 3 or smaller.

(1) Silicon Compound

Each of R² in the general formula [1], R⁴ in the general formula [2] and R⁶ in the general formula [3] is a water-repellent functional group. By reaction of an imide group of the sulfonimide derivative or a methide group of the sulfonmethide derivative with a silanol group on a surface of a wafer, a moiety containing the water-repellent functional group is fixed to the wafer surface whereby a water-repellent protective film is formed on the wafer surface.

Specific examples of the sulfonimide derivative represented by the above general formula [1] are: N-(alkylsilyl)bis(methanesulfonyl)imides such as N-(trimethylsilyl)bis(methanesulfonyl)imide, N-(ethyldimethylsilyl)bis(methanesulfonyl)imide, N-(diethylmethylsilyl)bis(methanesulfonyl)imide, N-(triethylsilyl)bis(methanesulfonyl)imide, N-(propyldimethylsilyl)bis(methanesulfonyl)imide, N-(dipropylmethylsilyl)bis(methanesulfonyl)imide, N-(tripropylsilyl)bis(methanesulfonyl)imide, N-(butyldimethylsilyl)bis(methanesulfonyl)imide, N-(pentyldimethylsilyl)bis(methanesulfonyl)imide, N-(hexyldimethylsilyl)bis(methanesulfonyl)imide, N-(heptyldimethylsilyl)bis(methanesulfonyl)imide, N-(octyldimethylsilyl)bis(methanesulfonyl)imide, N-(nonyldimethylsilyl)bis(methanesulfonyl)imide, N-(decyldimethylsilyl)bis(methanesulfonyl)imide, N-(undecyldimethylsilyl)bis(methanesulfonyl)imide, N-(dodecyldimethylsilyl)bis(methanesulfonyl)imide, N-(tridecyldimethylsilyl)bis(methanesulfonyl)imide, N-(tetradecyldimethylsilyl)bis(methanesulfonyl)imide, N-(pentadecyldimethylsilyl)bis(methanesulfonyl)imide, N-(hexadecyldimethylsilyl)bis(methanesulfonyl)imide, N-(heptadecyldimethylsilyl)bis(methanesulfonyl)imide, N-(octadecyldimethylsilyl)bis(methanesulfonyl)imide, N-(dimethylsilyl)bis(methanesulfonyl)imide, N-(methylsilyl)bis(methanesulfonyl)imide, N-(diethylsilyl)bis(methanesulfonyl)imide, N-(ethylsilyl)bis(methanesulfonyl)imide, N-(ethylmethylsilyl)bis(methanesulfonyl)imide and N-(dipropylsilyl)bis(methanesulfonyl)imide; N-(fluoroalkylsilyl)bis(methanesulfonyl)imides such as N-(trifluoropropyldimethylsilyl)bis(methanesulfonyl)imide, N-(pentafluorobutyldimethylsilyl)bis(methanesulfonyl)imide, N-(heptafluoropentyldimethylsilyl)bis(methanesulfonyl)imide, N-(nonafluorohexyldimethylsilyl)bis(methanesulfonyl)imide, N-(undecafluoroheptyldimethylsilyl)bis(methanesulfonyl)imide, N-(tridecafluorooctyldimethylsilyl)bis(methanesulfonyl)imide, N-(pentadecafluorononyldimethylsilyl)bis(methanesulfonyl)imide, N-(heptadecafluorodecyldimethylsilyl)bis(methanesulfonyl)imide and N-(trifluoropropylmethylsilyl)bis(methanesulfonyl)imide; and compounds obtained by replacing methanesulfonyl moieties of the above N-(alkylsilyl)bis(methanesulfonyl)imides and N-(fluoroalkylsilyl)bis(methanesulfonyl)imides with ethanesulfonyl, propanesulfonyl, octanesulfonyl, fluorosulfonyl, trifluoromethanesulfonyl, pentafluoroethanesulfonyl, heptafluoropropanesulfonyl, nonafluorobutanesulfonyl, tridecafluorohexanesulfonyl and the like.

In terms of the water repellency imparting effect, R¹ in the general formula [1] is preferably a group selected from the group consisting of a perfluoroalkyl group and a fluorine element. In terms of the environmental influence, R¹ in the general formula [1] is more preferably a group selected from the group consisting of a perfluoroalkyl group of 6 or less carbon atoms and a fluorine element.

Further, R² in the general formula [1] is each independently preferably a C₁-C₈ monovalent hydrocarbon group in which a part or all of hydrogen elements may be substituted with a fluorine element, more preferably a C₁-C₄ monovalent hydrocarbon group in which a part or all of hydrogen elements may be substituted with a fluorine element, in terms of the water repellency imparting effect. It is also preferable that, in the general formula [1], a is 1 and b is 0. In terms of the water repellency imparting effect, it is more preferable that at least two of R² in the general formula [1] are methyl.

Specific examples of the sulfonimide derivative represented by the above general formula [2] are compounds obtained by replacing bis(methanesulfonyl)imide moieties of the above-mentioned specific examples of the sulfonimide derivative represented by the general formula [1] with N,N-methane-1,3-bis(sulfonyl)imide, N,N-ethane-1,3-bis(sulfonyl)imide, N,N-propane-1,3-bis(sulfonyl)imide, N,N-butane-1,3-bis(sulfonyl)imide, N,N-pentane-1,3-bis(sulfonyl)imide, N,N-hexane-1,3-bis(sulfonyl)imide, N,N-heptane-1,3-bis(sulfonyl)imide, N,N-octane-1,3-bis(sulfonyl)imide, N,N-difluoromethane-1,3-bis(sulfonyl)imide, N,N-tetrafluoroethane-1,3-bis(sulfonyl)imide, N,N-hexafluoropropane-1,3-bis(sulfonyl)imide, N,N-octafluorobutane-1,3-bis(sulfonyl)imide, N,N-decafluoropentane-1,3-bis(sulfonyl)imide, N,N-dodecafluorohexane-1,3-bis(sulfonyl)imide, N,N-tetradecafluoroheptane-1,3-bis(sulfonyl)imide, N,N-hexadecafluorooctane-1,3-bis(sulfonyl)imide and the like.

In terms of the water repellency imparting effect, R³ in the general formula [2] is preferably a perfluoroalkylene group. In terms of the environmental influence, R³ in the general formula [2] is more preferably a perfluoroalkylene group of 6 or less carbon atoms.

Further, R⁴ in the general formula [2] is each independently preferably a C₁-C₈ monovalent hydrocarbon group in which a part or all of hydrogen elements may be substituted with a fluorine element, more preferably a C₁-C₄ monovalent hydrocarbon group in which a part or all of hydrogen elements may be substituted with a fluorine element, in terms of the water repellency imparting effect. It is also preferable that, in the general formula [2], c is 1 and d is 0. In terms of the water repellency imparting effect, it is more preferable that at least two of R⁴ in the general formula [2] are methyl.

Specific examples of the sulfonmethide derivative represented by the above general formula [3] are: (alkyl silyl)tris(methanesulfonyl)methides such as (trimethylsilyl)tris(methanesulfonyl)methide, (ethyldimethylsilyl)tris(methanesulfonyl)methide, (diethylmethylsilyl)tris(methanesulfonyl)methide, (tri ethyl silyl)tris(methanesulfonyl)methide, (propyldimethylsilyl)tris(methanesulfonyl)methide, (dipropylmethylsilyl)tris(methanesulfonyl)methide, (tripropylsilyl)tris(methanesulfonyl)methide, (butyldimethylsilyl)tris(methanesulfonyl)methide, (pentyldimethylsilyl)tris(methanesulfonyl)methide, (hexyldimethylsilyl)tris(methanesulfonyl)methide, (heptyldimethylsilyl)tris(methanesulfonyl)methide, (octyldimethylsilyl)tris(methanesulfonyl)methide, (nonyldimethylsilyl)tris(methanesulfonyl)methide, (decyldimethylsilyl)tris(methanesulfonyl)methide, (undecyldimethylsilyl)tris(methanesulfonyl)methide, (dodecyl dim ethyl silyl)tris(methanesulfonyl)methide, (tridecyldimethylsilyl)tris(methanesulfonyl)methide, (tetradecyldimethylsilyl)tris(methanesulfonyl)methide, (pentadecyldimethylsilyl)tris(methanesulfonyl)methide, (hexadecyldimethylsilyl)tris(methanesulfonyl)methide, (heptadecyldimethylsilyl)tris(methanesulfonyl)methide, (octadecyldimethylsilyl)tris(methanesulfonyl)methide, (dimethylsilyl)tris(methanesulfonyl)methide, (methyl silyl)tris(methanesulfonyl)methide, (diethyl silyl)tris(methanesulfonyl)methide, (ethyl silyl)tris(methanesulfonyl)methide, (ethylmethylsilyl)tris(methanesulfonyl)methide and (dipropylsilyl)tris(methanesulfonyl)methide; (fluoroalkylsilyl)tris(methanesulfonyl)methides such as (trifluoropropyldimethylsilyl)tris(methanesulfonyl)methide, (pentafluorobutyldimethylsilyl)tris(methanesulfonyl)methide, (heptafluoropentyldimethylsilyl)tris(methanesulfonyl)methide, (nonafluorohexyldimethylsilyl)tris(methanesulfonyl)methide, (undecafluoroheptyldimethylsilyl)tris(methanesulfonyl)methide, (tridecafluorooctyldimethylsilyl)tris(methanesulfonyl)methide, (pentadecafluorononyldimethylsilyl)tris(methanesulfonyl)methide, (heptadecafluorodecyldimethylsilyl)tris(methanesulfonyl)methide and (trifluoropropylmethylsilyl)tris(methanesulfonyl)methide; and compounds obtained by replacing methanesulfonyl moieties of the above (alkyl silyl)tris(methanesulfonyl)methides and (fluoroalkylsilyl)tris(methanesulfonyl)methides with ethanesulfonyl, propanesulfonyl, octanesulfonyl, fluorosulfonyl, trifluoromethanesulfonyl, pentafluoroethanesulfonyl, heptafluoropropanesulfonyl, nonafluorobutanesulfonyl, tridecafluorohexanesulfonyl and the like.

In terms of the water repellency imparting effect, R⁵ in the general formula [3] is preferably a group selected from the group consisting of a perfluoroalkyl group and a fluorine element. In terms of the environmental influence, R⁵ in the general formula [3] is more preferably a group selected from the group consisting of a perfluoroalkyl group of 6 or less carbon atoms and a fluorine element.

Further, R⁶ in the general formula [3] is each independently preferably a C₁-C₈ monovalent hydrocarbon group in which a part or all of hydrogen elements may be substituted with a fluorine element, more preferably a C₁-C₄ monovalent hydrocarbon group in which a part or all of hydrogen elements may be substituted with a fluorine element, in terms of the water repellency imparting effect. It is also preferable that, in the general formula [3], e is 1 and f is 0. In terms of the water repellency imparting effect, it is more preferable that at least two of R⁶ in the general formula [3] are methyl.

When the silicon compound is in liquid form, it is feasible to supply a liquid of the silicon compound as the water-repellent protective film forming agent to the wafer surface. It is alternatively feasible to supply a liquid chemical in which the liquid silicon compound is dissolved in and diluted with an organic solvent to the wafer surface. When the silicon compound is in solid form, it is feasible to supply a liquid chemical in which the solid silicon compound is dissolved in and diluted with an organic solvent to the wafer surface.

(2) Solvent

The water-repellent protective film forming liquid chemical according to the present invention is a solution in which the above silicon compound is dissolved in and diluted with an organic solvent. It is preferable that the concentration of the silicon compound is 0.01 to 25 mass % based on 100 mass % of the total amount of the silicon compound and the organic solvent because, within such a concentration range, it becomes easy to uniformly form a protective film on a silicon element-containing surface of a wafer. When the concentration of the silicon compound is lower than 0.01 mass %, the water repellency imparting effect tends to become insufficient. When the concentration of the silicon compound is higher than 25 mass %, there arises a fear that the silicon compound causes erosion of the wafer surface or remains as an impurity on the wafer surface. It is unfavorable to contain the silicon compound at such high concentration in terms of the cost effectiveness. The concentration of the silicon compound is more preferably 0.1 to 15 mass %, still more preferably 0.5 to 10 mass %.

As the organic solvent in the water-repellent protective film forming liquid chemical, there can suitably be used an aprotic solvent such as hydrocarbon, ester, ether, ketone, halogen-containing solvent, sulfoxide-based solvent, lactone-based solvent, carbonate-based solvent, OH-free polyalcohol derivative, NH-free nitrogen-containing solvent or silicone solvent, a thiol, or a mixture thereof. Among others, a hydrocarbon, an ester, an ether, a halogen-containing solvent, an OH-free polyalcohol derivative and a mixture thereof are preferred because the use of such a solvent enables the formation of a water-repellent protective film on a silicon element-containing wafer surface in a short time. Particularly preferred are a hydrocarbon and an ether.

Examples of the hydrocarbon are hexane, heptane, octane, nonane, decane, dodecane, tetradecane, hexadecane, octadecane, eicosane, cyclohexane, methylcyclohexane, decalin, benzene, toluene, xylene, diethylbenzene and the like.

Examples of the ester are ethyl acetate, propyl acetate, butyl acetate, ethyl acetoacetate and the like.

Examples of the ether are diethyl ether, dipropyl ether, ethyl butyl ether, dibutyl ether, ethyl amyl ether, diamyl ether, methyl cyclopentyl ether, ethyl hexyl ether, dihexyl ether, dioctyl ether, diphenyl ether, tetrahydrofuran, dioxane, methyl perfluoropropyl ether, methyl perfluorobutyl ether, ethyl perfluorobutyl ether, methyl perfluorohexyl ether, ethyl perfluorohexyl ether and the like.

Examples of the ketone are acetone, acetylacetone, methyl ethyl ketone, methyl propyl ketone, methyl butyl ketone, cyclohexanone, isophorone and the like.

Examples of the halogen-containing solvent are: perfluorocarbons such as perfluorooctane, perfluorononane, perfluorocyclopentane, perfluorocyclohexane, hexafluorobenzene and the like; hydrofluorocarbons such as 1,1,1,3,3-pentafluorobutane, octafluorocyclopentane, 2,3-dihydrodecafluoropentane, Zeorora (available from Zeon Corporation) and the like; hydrofluoroethers such as methyl perfluoroisobutyl ether, methyl perfluorobutyl ether, ethyl perfluorobutyl ether, ethyl perfluoroisobutyl ether, Asahiklin AE-3000 (available from Asahi Glass Co., Ltd.), Novec 7100, Novec 7200, Novec 7300, Novec 7600 (each available from 3M Company) and the like; chlorocarbons such as tetrachloromethane and the like; hydrochlorocarbons such as chloroform and the like; hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene, 1,2-dichloro-3,3,3-trifluoropropene and the like; perfluoroethers; perfluoropolyethers; and the like.

Examples of the sulfoxide-based solvent are dimethyl sulfoxide and the like.

Examples of the lactone-based solvent are γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, ε-hexanolactone and the like.

Examples of the carbonate-based solvent are dimethyl carbonate, ethyl methyl carbonate, diethyl carbonate, propene carbonate and the like.

Examples of the OH-free polyalcohol derivative are ethylene glycol dimethyl ether, ethylene glycol diethyl ether, ethylene glycol dibutyl ether, ethylene glycol monomethyl ether acetate, ethylene glycol monoethyl ether acetate, ethylene glycol monobutyl ether acetate, ethylene glycol diacetate, diethylene glycol dimethyl ether, diethylene glycol ethyl methyl ether, diethylene glycol diethyl ether, diethylene glycol butyl methyl ether, diethylene glycol dibutyl ether, diethylene glycol monomethyl ether acetate, diethylene glycol monoethyl ether acetate, diethylene glycol monobutyl ether acetate, diethylene glycol diacetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol dimethyl ether, propylene glycol diethyl ether, propylene glycol dibutyl ether, propylene glycol monomethyl ether acetate, propylene glycol monoethyl ether acetate, propylene glycol monobutyl ether acetate, propylene glycol diacetate, dipropylene glycol dimethyl ether, dipropylene glycol methyl propyl ether, dipropylene glycol diethyl ether, dipropylene glycol dibutyl ether, dipropylene glycol monomethyl ether acetate, dipropylene glycol monoethyl ether acetate, dipropylene glycol monobutyl ether acetate, dipropylene glycol diacetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol dimethyl ether, butylene glycol monomethyl ether acetate, butylene glycol diacetate, glycerin triacetate and the like.

Examples of the NH-free nitrogen-containing solvent are N,N-dimethylformamide, N,N-dimethylacetamide, N-methyl-2-pyrrolidone, triethylamine, pyridine and the like.

Examples of the silicone solvent are hexamethyldisiloxane, octamethyltrisiloxane, decamethyltetrasiloxane, dodecamethylpentasiloxane and the like.

Examples of the thiol are 1-hexanethiol, 2-methyl-1-pentanethiol, 3-methyl-1-pentanethiol, 4-methyl-1-pentanethiol, 2,2-dimethyl-1-butanethiol, 3,3-dimethyl-1-butanethiol, 2-ethyl-1-butanethiol, 1-heptanethiol, benzylthiol, 1-octanethiol, 2-ethyl-1-hexanethiol, 1-nonanethiol, 1-decanethiol, 1-undecanethiol, 1-dodedanethiol, 1-tridecanethiol and the like.

(3) Additive

To the liquid protective film forming agent or liquid chemical of the present invention, an additive such as polymerization inhibitor, chain transfer agent, antioxidant or the like may be added to increase the stability of the agent or liquid chemical. Examples of the additive are 4-methoxyphenol, dibutylhydroxytoluene, butylhydroxyanisol, 1,4-benzenediol, 2-(1,1-dimethylethyl)-1,4-benzenediol, 1,4-benzoquinone, 1-octanethiol, 1-nonanethiol, 1-decanethiol, 1-undecanethiol, 1-dodecanethiol, octyl-3,5-di-tert-butyl-4-hydroxy-hydrocinnamic acid (available as Irganox 1135 from BASF Corporation), δ-tert-butyl-2,4-xylenol and the like.

In terms of the cleanliness of the liquid protective film forming agent or liquid chemical, the additive is preferably in liquid form. Particularly preferred are 1-dodecanethiol, octyl-3,5-di-tert-butyl-4-hydroxy-hydrocinnamic acid (available as Irganox 1135 from BASF Corporation), δ-tert-butyl-2,4-xylenol and the like, each of which is liquid at e.g. 25° C. under atmospheric pressure.

(4) Cleanliness of Liquid Chemical (Liquid Chemical Raw Materials)

It is preferable that the total amount of water contained in the water-repellent protective film forming agent and the organic solvent before preparation of the liquid chemical is 5000 mass ppm or less relative to the total amount of the water-repellent protective film forming agent and the organic solvent. When the total amount of water is more than 5000 mass ppm, the water repellency imparting effect of the silicon compound may be lowered. For this reason, it is preferable that the total amount of water is as less as possible. The total amount of water is more preferably 500 mass ppm or less, still more preferably 200 mass ppm or less. The less amount of water is preferred in view of the fact that the more amount of water present, the more likely the storage stability of the liquid chemical is to be deteriorated. The total amount of water is particularly preferably 100 mass ppm or less, more particularly preferably 50 mass ppm or less. Although it is preferable that the total amount of water is as less as possible, the total amount of water may be 0.1 mass ppm or more as long as it is within the above range. It is consequently preferable that the silicon compound and the organic solvent before preparation of the liquid chemical are not high in water content.

It is also preferable that, in a particle measurement made in a liquid phase of the liquid chemical by a light scattering type in-liquid particle detector, the number of particles of diameter larger than 0.2 μm is 100 or less per 1 mL of the liquid chemical. When the number of particles of diameter larger than 0.2 μm exceeds 100 per 1 mL of the liquid chemical, there unfavorably arises a risk of damage to the pattern by the particles. This can lead to a deterioration in device yield and reliability. When the number of particles of diameter larger than 0.2 μm is 100 or less per 1 mL of the liquid chemical, it is favorably feasible to omit or reduce the cleaning of the wafer surface with a solvent or water after the formation of the protective film. Although it is preferable that the number of particles of diameter larger than 0.2 μm per 1 mL of the liquid chemical is as less as possible, the number of particles of diameter larger than 0.2 μm may be 1 or more per 1 mL of the liquid chemical as long as it is within the above range. In the present invention, the particle measurement in the liquid phase of the liquid chemical can be made by a commercially available measurement device based on a laser light scattering type in-liquid particle measuring method using a laser as a light source. The term “particle diameter” as used herein means a light scattering equivalent diameter with reference to a PSL (polystyrene latex) standard particle.

Herein, the particles include particles such as dust, dirt, organic solid matter and inorganic solid matter contained as impurities in the raw materials as well as particles such as dust, dirt, organic solid matter and inorganic solid matter introduced as contaminants during preparation of the liquid chemical, and refer to particles finally present without being dissolved in the liquid chemical.

It is further preferable that the amount of each of Na, Mg, K, Ca, Mn, Fe, Cu, Li, Al, Cr, Ni, Zn and Ag elements (metal impurities) in the liquid chemical is 0.1 mass ppb or less relative to the total amount of the liquid chemical. When the amount of each metal impurity element is more than 0.1 mass ppb relative to the total amount of the liquid chemical, there unfavorably arises a risk of increase in device junction leakage current. This can lead to a deterioration in device yield or reliability. When the amount of each metal impurity element is 0.1 mass ppb or less relative to the total amount of the liquid chemical, it is favorably feasible to omit or reduce the cleaning of the wafer surface (the surface of the protective film) with a solvent or water after the formation of the protective film. For this reason, it is preferable that the amount of the metal impurities in the liquid chemical is as less as possible. However, the amount of each metal impurity element may be 0.001 mass ppb or more relative to the total amount of the liquid chemical as long as it is within the above range.

2. Water-Repellent Protective Film

In the present invention, the water-repellent protective film refers to a film formed on a wafer surface to decrease the wettability of the wafer surface and impart water repellency to the wafer surface. The term “water repellency” as used herein means to decrease a surface energy of an article surface and thereby reduce an interaction such as hydrogen bond or intermolecular force (at an interface) between water or another liquid and the article surface. The water repellency shows a great interaction reducing effect against water, but shows a certain interaction reducing effect against a mixed liquid of water and a liquid other than water or against a liquid other than water. The contact angle of the liquid to the article surface can be increased with reduction of the interaction. Herein, the water-repellent protective film may be formed of the silicon compound or a reaction product containing the silicon compound as a main component.

3. Wafer

As the wafer, there can be used a wafer having on a surface thereof a film which contains silicon element in the form of silicon, silicon oxide, silicon nitride or the like, or a wafer having an uneven pattern whose surface at least partially contains silicon element in the form of silicon, silicon oxide, silicon nitride or the like. Even in the case of using a wafer composed of a plurality of components containing at least silicon element, the protective film can be formed on a surface of such silicon element-containing component. The wafer composed of a plurality of components may be those in which silicon element-containing component such as silicon, silicon oxide, silicon nitride or the like is present on the wafer surface, or those in which at least a part of the uneven pattern on the wafer surface is formed of silicon element-containing component such as silicon, silicon oxide, silicon nitride or the like. It is herein noted that the area of the wafer where the protective film can be formed from the liquid chemical is a surface of silicon element-containing part of the uneven pattern.

In general, the wafer having the fine uneven pattern on its surface is obtained by the following procedure. First, a resist with a desired uneven pattern is formed by applying a resist material to the smooth surface of the wafer, exposing the applied resist to light through a resist mask and removing by etching an exposed portion or unexposed portion of the resist. The resist with the uneven pattern may alternatively be formed by pressing a mold with a pattern against the resist. Next, the wafer is subjected to etching. In this etching step, portions of the wafer surface corresponding to the recess portions of the resist pattern is selectively etched. Finally, the resist is removed whereby the wafer with the fine uneven pattern is obtained.

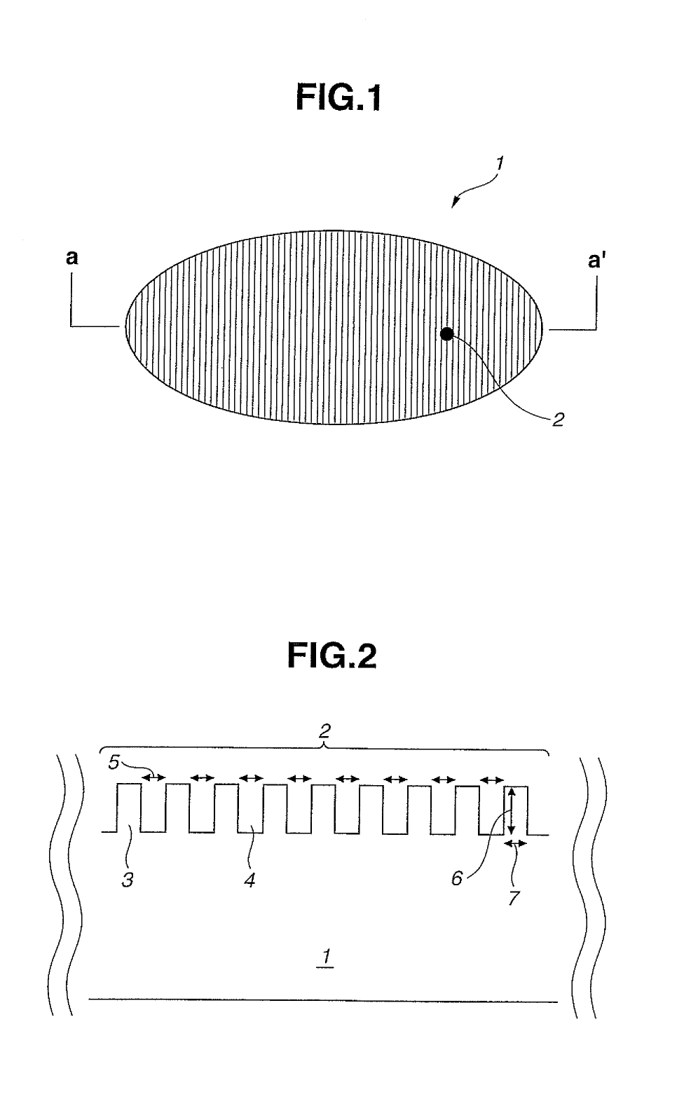

After the formation of the fine uneven pattern on the surface of the wafer, the wafer surface is cleaned with a water-based cleaning liquid; and then the water-based cleaning liquid is removed by drying or the like. During such cleaning process, the formed pattern is likely to cause a pattern collapse phenomenon when the width of the recess portions is small and the aspect ratio of the projection portions is high. The dimensions of the uneven pattern are defined as shown in FIGS. 1 and 2. FIG. 1 is a schematic perspective view of a wafer 1 having on a surface thereof a fine uneven pattern 2. FIG. 2 is a view showing a part of a-a′ cross section of FIG. 1. As shown in FIG. 2, a width 5 of the recess portions is determined as an interval between adjacent projection portions 3; and an aspect ratio of the projection portions is determined by dividing a height 6 of the projection portions by a width 7 of the projection portions. The pattern collapse tends to occur during the cleaning process when the width of the recess portions is 70 nm or smaller, particularly 45 nm or smaller, and the aspect ratio of the projection portions is 4 or higher, particularly 6 or higher.

4. Wafer Cleaning Method

The wafer, which has the fine uneven pattern formed on the surface thereof by etching as mentioned above, may be cleaned with a water-based cleaning liquid so as to remove etching residues in advance of the wafer cleaning method of the present invention. The wafer may be further cleaned by replacing the water-based cleaning liquid remaining in the recess portions after the above cleaning step with a cleaning liquid different from the water-based cleaning liquid (hereinafter referred to as “cleaning liquid A”).

As the water-based cleaning liquid, there can be used water or an aqueous solution containing in water at least one kind selected from organic solvent, hydrogen peroxide, ozone, acid, alkali and surfactant (e.g. with a water content of 10 mass % or more).

As the cleaning liquid A, there can be used an organic solvent, a mixture of the organic solvent with a water-based cleaning liquid, or a cleaning liquid containing at least one kind selected from acid, alkali and surfactant in the organic solvent or in the mixture of the organic solvent with the water-based cleaning liquid.

In the present invention, there is no particular limitation on the wafer cleaning technique as long as the cleaning is performed by means of a cleaning machine capable of retaining the liquid protective film forming agent or liquid chemical or the cleaning liquid at least in the recess portions of the uneven pattern of the wafer. It is feasible to adopt a single wafer process such as a cleaning process using a spin washing machine in which wafers are cleaned one by one by rotating the wafer in a nearly horizontal position while supplying the liquid to the vicinity of the rotation center, or a batch process using a washing machine in which a plurality of wafers are cleaned together by immersion in the liquid within a cleaning chamber. There is also no particular limitation on the forms of the protective film forming agent or liquid chemical and the cleaning liquid supplied to at least the recess portions of the uneven pattern of the wafer as long as each of the agent or liquid chemical and the cleaning liquid is in a liquid state when retained in the recess portions. The protective film forming agent or liquid chemical and the cleaning liquid can be each supplied in e.g. liquid form, vapor form or the like.

Examples of the organic solvent preferably usable as the cleaning liquid A are hydrocarbons, esters, ethers, ketones, halogen-containing solvents, sulfoxide-based solvents, lactone-based solvents, carbonate-based solvents, alcohols, polyol derivatives, nitrogen-containing solvents and the like.

The liquid protective film forming agent or protective film forming liquid chemical of the present invention is used by replacing the water-based cleaning liquid or the cleaning liquid A with the agent or liquid chemical. The replaced agent or liquid chemical may be replaced with a cleaning liquid different from the agent or liquid chemical (hereinafter referred to as “cleaning liquid B”).

After the cleaning of the wafer with the water-based cleaning liquid or the cleaning liquid A, the cleaning liquid is replaced with the liquid protective film forming agent or protective film forming liquid chemical as mentioned above. While the agent or liquid chemical is retained at least in the recess portions of the uneven pattern, the protective film is formed on at least the surfaces of the recess portions of the uneven pattern. In the present invention, the protective film is not necessarily continuously formed and is not necessarily uniformly formed. It is however preferable that the protective film is continuously and uniformly formed to impart higher water repellency.

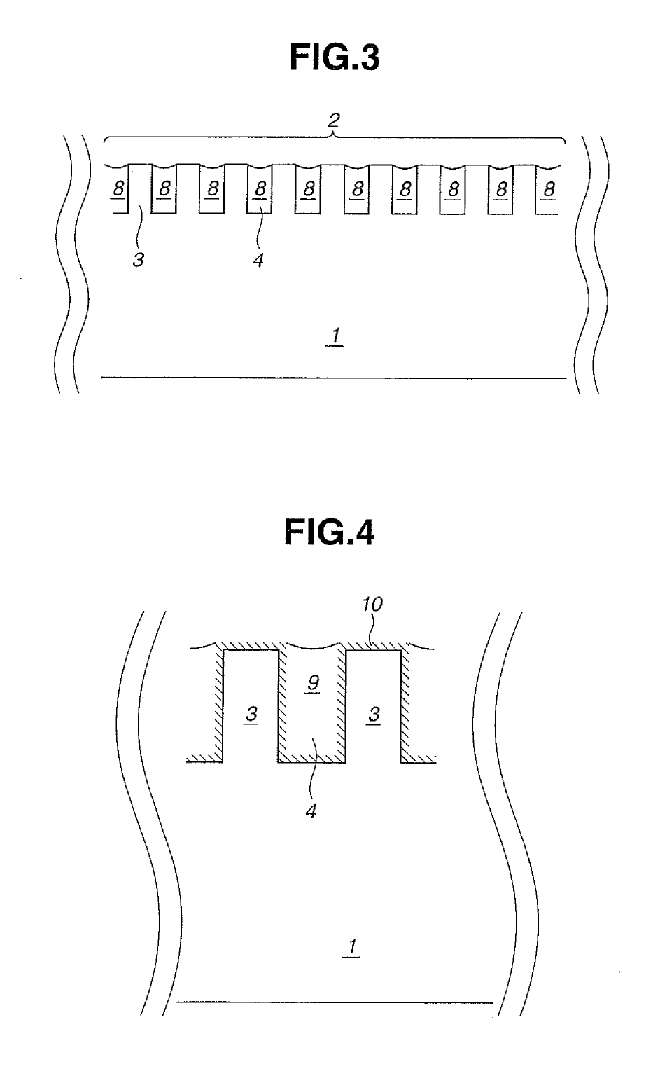

FIG. 3 is a schematic view showing a state where the liquid protective film forming agent or protective film forming liquid chemical 8 is retained in the recess portions 4. The schematic view of FIG. 3 shows corresponds to a part of a-a′ cross section of FIG. 1. In this state, the protective film is formed on the surfaces of the recess portions 4 to impart water repellency to the surfaces of the recess portions 4.

When the temperature of the liquid protective film forming agent or protective film forming liquid chemical is increased, it becomes easy to form the protective film in a shorter time. The temperature at which the uniform protective film can be readily formed from the agent or liquid chemical is higher than or equal to 10° C. and lower than a boiling point of the agent or liquid chemical. In particular, the agent or liquid chemical is preferably retained at a temperature higher than or equal to 15° C. and lower than or equal to a temperature 10° C. lower than the boiling point of the agent or liquid chemical. It is preferable to maintain the temperature of the liquid protective film forming agent or liquid chemical at the above-mentioned temperature even when the agent or liquid chemical is retained at least in the recess portions of the uneven pattern. Herein, the boiling point of the liquid chemical means a boiling point of any component present in the largest amount by mass ratio among the components of the protective film forming liquid chemical.

After the formation of the protective film, the protective film may be subjected to drying after replacing the liquid protective film forming agent or liquid chemical remaining at least in the recess portions of the uneven pattern with the cleaning liquid B. As the cleaning liquid B, there can be used a water-based cleaning liquid, an organic solvent, a mixture of the water-based cleaning liquid and the organic solvent, a mixture thereof with at least one kind selected from acid, alkali and surfactant, a mixture thereof with the liquid protective film forming agent or protective film forming liquid chemical, or the like. In terms of the removal of particles and metal impurities, the cleaning liquid B is preferably water, an organic solvent or a mixture of the organic solvent with water.

Examples of the organic solvent preferably usable as the cleaning liquid B are hydrocarbon, ester, ether, ketone, halogen-containing solvent, sulfoxide-based solvent, alcohol, polyol derivative, nitrogen-containing solvent and the like.

There are cases where, when an organic solvent is used as the cleaning liquid B, the protective film formed on the wafer surface from the liquid protective film forming agent or liquid chemical of the present invention is less likely to be deteriorated in water repellency.

FIG. 4 is a schematic view showing a state where a liquid is retained in the recess portions 4 to which water repellency has been imparted by the liquid protective film forming agent or protective film forming liquid chemical. The schematic view of FIG. 4 shows corresponds to a part of a-a′ cross section of FIG. 1. The surface of the uneven pattern is made water repellent as the protective film 10 is formed on the surface of the uneven pattern from the liquid protective film forming agent or liquid chemical. Even when the liquid 9 is removed from the uneven pattern, the protective film 10 is maintained on the wafer surface.

Assuming that water is retained on the surfaces of the recess portions in a state where the protective film 10 has been formed from the liquid protective film forming agent or protective film forming liquid chemical at least on the surfaces of the recess portions of the uneven pattern of the wafer, the contact angle is preferably 50 to 130°. In this contact angle range, a pattern collapse is unlikely to occur. The larger the contact angle, the higher the water repellency. The contact angle is more preferably 60 to 130°, still more preferably 65 to 130°. In addition, it is preferable that a decrease of the contact angle before and after the cleaning with the cleaning liquid B (i.e. the contact angle before the cleaning with the cleaning liquid B—the contact angle after the cleaning with the cleaning liquid B) is 10° or less.

Then, the liquid retained in the recess portions 4 on which the protective film 10 has been formed from the liquid protective film forming agent or liquid chemical is removed by drying. The liquid retained in the recess portions may be the liquid protective film forming agent or liquid chemical, the cleaning liquid B or a mixed liquid thereof. The mixed liquid is a mixture of the protective film forming agent and the cleaning liquid B or a mixture in which the respective components of the protective film forming liquid chemical are contained at lower concentration than the liquid chemical. Namely, the mixed liquid may be a liquid in the middle of replacing the liquid protective film forming agent or liquid chemical with the cleaning liquid B, or may be a liquid prepared in advance by mixing the silicon compound with the cleaning liquid B. In terms of the cleanliness of the wafer, water, the organic solvent or a mixture thereof is preferred. After the liquid is once removed from the surface of the uneven pattern, the cleaning liquid B may be retained on the surface of the uneven pattern and then removed by drying.

In the case of cleaning the surface of the uneven pattern with the cleaning liquid B after the formation of the protective film, the cleaning time, that is, the time of retaining the cleaning liquid B is preferably 10 seconds or longer, more preferably 20 seconds or longer, in terms of the removal of the particles or impurities from the surface of the uneven pattern. In terms of the water repellency maintaining effect of the protective film on the surface of the uneven pattern, there is a tendency that the water repellency of the wafer surface can be easily maintained even after the cleaning when the organic solvent is used as the cleaning liquid B. On the other hand, the productivity of the wafer is deteriorated when the cleaning time is too long. The cleaning time is thus preferably 15 minutes or shorter.

By the drying, the liquid retained in the uneven pattern is removed. It is preferable to perform the drying by a known drying technique such as spin drying, IPA (2-propanol) steam drying, Marangoni drying, heat drying, hot-air drying, air-blow drying or vacuum drying.

The protective film 10 may be removed after the drying. For removal of the water-repellent protective film, it is effective to cleave C—C bond and C—F bond in the water-repellent protective film. There is no particular limitation on the bond cleavage technique as long as it is capable of cleaving the above-mentioned bond. For example, it is feasible to treat the wafer surface by light irradiation, heating, ozone exposure, plasma irradiation, corona discharge or the like.

In the case of removing the protective film 10 by light irradiation, it is preferable to irradiate an ultraviolet light with wavelengths shorter than 340 nm and 240 nm, which respectively correspond to 83 kcal/mol and 116 kcal/mol, i.e., the bond energies of C—C bond and C—F bond in the protective film 10. As a light source, there can be used a metal halide lamp, a low-pressure mercury lamp, a high-pressure mercury lamp, an excimer lamp, a carbon arc lamp or the like. In the case of using a metal halide lamp, the irradiation intensity of the ultraviolet light is preferably 100 mW/cm² or higher, more preferably 200 mW/cm² or higher, as measured by an illuminometer (such as an irradiation intensity meter UM-10 manufactured by Konica Minolta Sensing, Inc. with a light receptor UM-360 [peak sensitivity wavelength: 365 nm, measurement wavelength range: 310 to 400 nm]). When the irradiation intensity is lower than 100 mW/cm², it takes a long time to remove the protective film 10. It is preferable to use the low-pressure mercury lamp because the low-pressure mercury lamp enables irradiation of an ultraviolet light with shorter wavelengths so as to, even if the irradiation intensity is low, remove the protective film 10 in a short time.

In the case of removing the protective film 10 by light irradiation, it is preferable to generate ozone in parallel with decomposing components of the protective film 10 by irradiation with an ultraviolet light and then induce oxidation volatilization of the components of the protective film 10 by the ozone for shortening of treatment time. As a light source, there can be used a low-pressure mercury lamp, an excimer lamp or the like. The wafer may be heated while being subjected to light irradiation.

In the case of heating the wafer, the heating temperature of the wafer is preferably 400 to 1000° C., more preferably 500 to 900° C.; and the heating time of the wafer is preferably 10 seconds to 60 minutes, more preferably 30 seconds to 10 minutes. The heating may be done in combination with ozone exposure, plasma irradiation, corona discharge or the like. The wafer may be subjected to light irradiation while heating.

As the technique of removing the protective film 10 by heating, it is feasible to bring the wafer into a heat source or place the wafer in a heated atmosphere such as heat treatment furnace. Even in the case of treating a plurality of wafers, energy for removal of the protective film 10 can be applied uniformly to the wafer surface by placement of the wafers in the heated atmosphere. Thus, the placement of the wafer in the heated atmosphere is industrially advantageous in terms of easy operation, short treatment time and high treatment capability.

In the case of exposing the wafer to ozone, it is preferable to supply the wafer surface with ozone generated by ultraviolet radiation from a low-pressure mercury lamp etc., low-temperature discharge under high voltage application, or the like. The wafer may be subjected to light irradiation or heating while being exposed to ozone.

The protective film on the wafer surface can be efficiently removed by any combination of the light irradiation treatment, the heating treatment, the ozone exposure treatment, the plasma irradiation treatment and the corona discharge treatment.

### EXAMPLES

The embodiments of the present invention will be described in more detail below by way of the following examples. It should be understood that the present invention is not limited to the following examples.

A method of forming an uneven pattern on a surface of a wafer and a method of replacing a cleaning liquid retained at least in recess portions of the uneven pattern with another cleaning liquid have been variously studied as discussed in other literatures and have already been established. On this account, the water repellency imparting effect of the liquid protective film forming agent or protective film forming liquid chemical was evaluated in the present invention. In the following examples, water, which is a typical water-based cleaning liquid, was used as the liquid brought into contact with the wafer surface for evaluation of the contact angle.

In the case of a wafer having an unevenly patterned surface, it is not possible to exactly evaluate the contact angle of a protective film 10 itself formed on the unevenly patterned surface of the wafer. The contact angle of a water drop is generally evaluated by dropping several microliters of water on a surface of a sample (substrate) and then measuring an angle between the water drop and the substrate surface according to JIS R 3257 “Testing Method of Wettability of Glass Substrate Surface”. In the case of a wafer having a pattern, however, the contact angle is enormously large. This is due to the Wenzel's effect or Cassie's effect by which the apparent contact angle of the water drop becomes increased under the influence of the surface shape (roughness) of the substrate on the contact angle.

In view of the above facts, the following examples were each conducted by providing a wafer with a smooth surface, supplying a liquid protective film forming agent or liquid chemical to the smooth surface of the wafer to form a protective film on the wafer surface, and then, performing various evaluation tests on the assumption of the resulting protective film as a protective film formed on an unevenly patterned surface of a wafer. In each example, a silicon wafer having a smooth surface coated with a SiO₂ layer, called a “SiO₂-coated wafer”, was used as the wafer with the smooth surface.

The details of the respective examples will be explained below. In the following, explanations will be given of a method for the evaluation, a method for preparing the protective film forming liquid, a method for cleaning the wafer with the use of the liquid protective film forming agent or protective film forming liquid chemical, and results of the evaluation after the formation of the protective film on the wafer surface.

[Methods of Evaluation]

Evaluation of Contact Angle of Protective Film on Wafer Surface About 2 μl of pure water was dropped on the surface of the wafer on which the protective film was formed, followed by measuring the angle between the water drop and the wafer surface (as a contact angle) with a contact angle meter (manufactured by Kyowa Interface Science Co., Ltd.: CA-X Model).

### Example 1

(1) Preparation of Protective Film Forming Liquid Chemical

The protective film forming liquid chemical was prepared by dissolving N-(trimethylsilyl)bis(trifluoromethanesulfonyl)imide [(CF₃S(═O)₂)₂N—Si(CH₃)₃] as a silicon compound at a concentration of 0.2 mass % in decane as an organic solvent. At this time, the total amount of water contained in the raw materials, that is, decane and N-(trimethylsilyl)bis(trifluoromethanesulfonyl)imide was 10 mass ppm relative to the total amount of the decane and the N-(trimethylsilyl)bis(trifluoromethanesulfonyl)imide.

(2) Cleaning of Silicon Wafer

The silicon wafer with a smooth thermal oxide film (more specifically, a silicon wafer having on its surface a thermal oxide film of 1 μm thickness) was immersed in a 1 mass % aqueous solution of hydrogen fluoride at room temperature for 10 minutes, immersed in pure water at room temperature for 1 minute, and then, immersed in 2-propanol (iPA) at room temperature for 1 minute.

(3) Surface Treatment of Silicon Wafer with Protective Film Forming Liquid Chemical

The above-cleaned silicon wafer was immersed at 25° C. for 2 minutes in the protective film forming liquid chemical that had been prepared in the above section “(1) Preparation of Protective Film Forming Liquid Chemical”. After that, the silicon wafer was immersed in iPA at room temperature for 1 minute and immersed in pure water at room temperature for 1 minute. Finally, the silicon wafer was taken out from the pure water and dried by air blowing to remove the pure water on the surface of the silicon wafer.

Then, the evaluation was performed as mentioned above. As shown in TABLE 1, the initial contact angle before the surface treatment was less than 10°; and the contact angle after the surface treatment was 98°. As is apparent from these results, the water repellency imparting effect was confirmed.

TABLE 1

| | Protective film forming liquid chemical | | | | | |
|---|---|---|---|---|---|---|
| | | | | Total amount [mass ppm] | | |
| | | | | of water contained in silicon | | |
| | | | | compound and organic solvent | Evaluation results | |
| | | | | relative to total amount of | | Contact |
| | Silicon compound | | | silicon compound and organic | Initial | angle [°] |
| | | Concentration | Organic solvent | solvent before preparation of | contact | after surface |
| | Kind | [mass %] | Kind | liquid chemical | angle [°] | treatment |
| Example 1 | (CF₃S(═O)₂)₂N—Si(CH₃)₃ | 0.2 | Decane | 10 | <10 | 98 |
| Example 2 | (FS(═O)₂)₂N—Si(CH₃)₃ | 0.2 | Decane | 10 | <10 | 72 |
| Example 3 | (CF₃S(═O)₂)₂N—Si(CH₃)₃ | 0.03 | Decane | 10 | <10 | 74 |
| Example 4 | (CF₃S(═O)₂)₂N—Si(CH₃)₃ | 0.05 | Decane | 10 | <10 | 91 |
| Example 5 | (CF₃S(═O)₂)₂N—Si(CH₃)₃ | 0.5 | Decane | 10 | <10 | 99 |
| Example 6 | (CF₃S(═O)₂)₂N—Si(CH₃)₃ | 1 | Decane | 10 | <10 | 100 |
| Example 7 | (CF₃S(═O)₂)₂N—Si(CH₃)₃ | 3 | Decane | 10 | <10 | 100 |
| Example 8 | (CF₃S(═O)₂)₂N—Si(CH₃)₃ | 5 | Decane | 10 | <10 | 100 |
| Example 9 | (CF₃S(═O)₂)₂N—Si(CH₃)₃ | 0.5 | DnBE | 10 | <10 | 96 |
| Example 10 | (CF₃S(═O)₂)₂N—Si(CH₃)₃ | 0.5 | DnBE | 50 | <10 | 95 |
| Example 11 | (CF₃S(═O)₂)₂N—Si(CH₃)₃ | 0.5 | DnBE | 100 | <10 | 55 |
| Example 12 | (CF₃S(═O)₂)₂N—Si(CH₃)₃ | 0.5 | DiAE | 10 | <10 | 96 |
| Example 13 | (CF₃S(═O)₂)₂N—Si(CH₃)₃ | 0.5 | Decane/DiAE-95 | 10 | <10 | 98 |
| Example 14 | (CF₃S(═O)₂)₂N—Si(CH₃)₃ | 0.5 | Decane/DiAE-90 | 10 | <10 | 98 |
| Example 15 | (CF₃S(═O)₂)₂N—Si(CH₃)₃ | 0.5 | Decane/DiAE-70 | 10 | <10 | 98 |
| Example 16 | (CF₃S(═O)₂)₂N—Si(CH₃)₃ | 1 | Decane/DiAE-95 | 10 | <10 | 98 |
| Example 17 | (CF₃S(═O)₂)₂N—Si(CH₃)₃ | 2 | Decane/DiAE-95 | 10 | <10 | 98 |
| Example 18 | (CF₃S(═O)₂)₂N—Si(CH₃)₃ | 3 | Decane/DiAE-95 | 10 | <10 | 98 |
| Example 19 | (CF₃S(═O)₂)₂N—Si(CH₃)₃ | 3 | Decane/DiAE-95 | 50 | <10 | 98 |
| Example 20 | (CF₃S(═O)₂)₂N—Si(CH₃)₃ | 0.5 | Decane/Novec 7100-95 | 10 | <10 | 98 |
| Example 21 | (CF₃S(═O)₂)₂N—Si(CH₃)₃ | 1 | Decane/Novec 7100-95 | 10 | <10 | 99 |
| Example 22 | (CF₃S(═O)₂)₂N—Si(CH₃)₃ | 0.5 | PGMEA | 10 | <10 | 95 |
| Example 23 | (CF₃S(═O)₂)₂N—Si(CH₃)₃ | 0.5 | PGMEA | 50 | <10 | 91 |
| Example 24 | (CF₃S(═O)₂)₂N—Si(CH₃)₃ | 0.5 | PGMEA | 100 | <10 | 73 |
| Example 25 | (CF₃S(═O)₂)₂N—Si(CH₃)₃ | 0.5 | PGMEA | 200 | <10 | 59 |
| Example 26 | (CF₃S(═O)₂)₂N—Si(CH₃)₃ | 0.5 | Octamethyltrisiloxane | 10 | <10 | 97 |

### Examples 2 to 26

The wafer surface treatment was performed in the same manner as in Example 1, except for changing liquid chemical preparation conditions such as the kind of the silicon compound, the kind of the organic solvent, the concentration of the silicon compound and the total amount of water in the raw materials. After that, the evaluation was performed in the same manner as above. The results are summarized in TABLE 1.

In the table, “DnBE” refers to dinormalbutyl ether; “DiAE” refers to diisoamyl ether; “Decane/DiAE-95” refers to a mixed solvent of decane and DiAE at a mass ratio of 95:5; “Decane/DiAE-90” refers to a mixed solvent of decane and DiAE at a mass ratio of 90:10; “Decane/DiAE-70” refers to a mixed solvent of decane and DiAE at a mass ratio of 70:30; “Decane/Novec 7100-95” refers to a mixed solvent of decane and Novec 7100 (available from 3M Company) at a mass ratio of 95:5; and “PGMEA” refers to propylene glycol monomethyl ether acetate.

### Examples 27 to 29

The wafer surface treatment was performed in the same manner as in Example 5, except for adding an additive to the protective film forming liquid chemical of Example 5 and using the resulting liquid chemical. After that, the evaluation was performed in the same manner as above. The results are summarized in TABLE 2.

In the table, “BHT” refers to dibutylhydroxytoluene; and “tert-butylxylenol” refers to δ-tert-butyl-2,4-xylenol.

TABLE 2

| | Protective film forming liquid chemical | | | | | | | |
|---|---|---|---|---|---|---|---|---|
| | | | | | | Total amount [mass ppm] | | |
| | | | | | | of water contained in silicon | | |
| | | | | | | compound and organic solvent | Evaluation results | |
| | Silicon compound | | | Additive | | relative to total amount of | | Contact |
| | | Concen- | Organic | | Concen- | silicon compound and organic | Initial | angle [°] |
| | | tration | solvent | | tration | solvent before preparation of | contact | after surface |
| | Kind | [mass %] | Kind | Kind | [mass %] | liquid chemical | angle [°] | treatment |
| Example 27 | (CF₃S(═O)₂)₂N—Si(CH₃)₃ | 0.5 | Decane | 1-Dodecane- | 1 | 10 | <10 | 99 |
| | | | | thiol | | | | |
| Example 28 | (CF₃S(═O)₂)₂N—Si(CH₃)₃ | 0.5 | Decane | BHT | 0.1 | 10 | <10 | 99 |
| Example 29 | (CF₃S(═O)₂)₂N—Si(CH₃)₃ | 0.5 | Decane | tert-Butyl- | 0.1 | 10 | <10 | 99 |
| | | | | xylenol | | | | |

In the respective examples, the water repellency imparting effect was confirmed after the surface treatment with respect to the initial contact angle of less than 10° before the surface treatment.

### Comparative Example 1

The wafer surface treatment was performed in the same manner as in Example 1, except for changing liquid chemical preparation conditions such as the kind and concentration of the silicon compound as shown in TABLE 3. After that, the evaluation was performed in the same manner as above. In Comparative Example 1, the raw materials in TABLE 3 refer to the silicon compound and the organic solvent before the preparation of the liquid chemical.

In this Comparative Example 1 in which the protective film forming liquid chemical was prepared using trimethylmethoxysilane in place of N-(trimethylsilyl)bis(trifluoromethanesulfonyl)imide, the contact angle after the surface treatment was at a small level of less than 10°. No water repellency imparting effect was observed.

TABLE 3

| | | | | | Evaluation results | |
|---|---|---|---|---|---|---|
| | Protective film forming liquid chemical | | | | | Contact |
| | Silicon compound | | | Total amount [mass ppm] of water | Initial | angle [°] |
| | | Concentration | Organic solvent | contained in raw materials relative to | contact | after surface |
| | Kind | [mass %] | Kind | total amount of raw materials | angle [°] | treatment |
| Comparative | (CH₃)₃Si—OCH₃ | 3 | Decane | 10 | <10 | <10 |
| Example 1 | | | | | | |

| | | | | |
|---|---|---|---|---|
| Reference | Liquid chemical of 3 mass % (CH₃)₃SiCl in toluene | 50 | <10 | 65 |
| Example 1 | | | | |
| Reference | Liquid chemical of 3 mass % (CH₃)₃Si—OCH₃ | 50 | <10 | 84 |
| Example 2 | and 1 mass % CF₃SO₃H in PGMEA | | | |

### Reference Examples 1 and 2

The wafer surface treatment was performed in the same manner as in Example 1, except for using protective film forming liquid chemicals disclosed in Examples of Patent Documents 1 and 2. After that, the evaluation was performed in the same manner as above. The results are summarized in TABLE 3.

In Reference Example 1, the wafer surface treatment was performed by using the protective film forming liquid chemical in which 3 g of trimethylchlorosilane [(CH₃)₃SiCl] was mixed with 97 g of toluene with reference to Example 22 of Patent Document 1. As the contact angle after the surface treatment was 65°, the water repellency imparting effect was confirmed. In this Reference Example 1, the raw materials in TABLE 3 refer to the trimethylchlorosilane and toluene before the preparation of the liquid chemical.

In Reference Example 2, the wafer surface treatment was performed by using the protective film forming liquid chemical in which 3 g of trimethylmethoxysilane [(CH₃)₃Si—OCH₃] and 1 g of trifluoromethanesulfonic acid [CF₃SO₃H] were mixed with 96 g of PGMEA with reference to Example 4 of Patent Document 2. The water repellency imparting effect was also confirmed as the contact angle after the surface treatment was 84°. In this Reference Example 2, the raw materials in TABLE 3 refer to the trimethylmethoxysilane, trifluoromethanesulfonic acid and PGMEA before the preparation of the liquid chemical.

### Example 30

The wafer surface treatment was performed in the same manner as in Example 1, except for using N-(trimethylsilyl)bis(trifluoromethanesulfonyl)imide [(CF₃S(═O)₂)₂N—Si(CH₃)₃] as a liquid protective film forming agent in place of the protective film forming liquid chemical. After that, the evaluation was performed in the same manner as above. It is noted that N-(trimethylsilyl)bis(trifluoromethanesulfonyl)imide is in a liquid state at 25° C.

The initial contact angle before the surface treatment was less than 10°; and the contact angle after the surface treatment was 100°. Thus, the water repellency imparting effect was confirmed.

The liquid water-repellent protective film forming agent or protective film forming liquid chemical of the present invention had the same level of water repellency imparting effect as those of the protective film forming liquid chemicals of the above Reference Examples. Accordingly, the present invention has been found to provide a novel protective film forming agent or novel protective film forming liquid chemical capable of imparting the same level of water repellency as conventional protective film forming liquid chemicals, with no chlorine atom being contained in a water-repellent protective film forming component thereof and without the need to use a protective film formation promoting component as an essential component.

### DESCRIPTION OF REFERENCE NUMERALS

1: Wafer
2: Fine uneven pattern on wafer surface
3: Projection portion of pattern
4: Recess portion of pattern
5: Width of recess portion
6: Height of projection portion
7: Width of projection portion
8: Liquid water-repellent protective film forming agent or protective film forming liquid chemical retained in recess portion 4
9: Liquid retained in recess portion 4
10: Protective film

1. A water-repellent protective film forming agent for forming a water-repellent protective film on a silicon element-containing surface of a wafer, consisting of at least one kind of silicon compound selected from the group consisting of a sulfonimide derivative represented by the following general formula [1], a sulfonimide derivative represented by the following general formula [2] and a sulfonmethide derivative represented by the following general formula [3]
((R¹—S(═O)₂)₂N)ₐSi(H)_{b}(R²)_{4-a-b} [1]
where R¹ is each independently a group selected from the group consisting of a C₁-C₈ monovalent hydrocarbon group in which a part or all of hydrogen elements may be substituted with a fluorine element, and a fluorine element; R² is each independently a C₁-C₁₈ monovalent hydrocarbon group in which a part or all of hydrogen elements may be substituted with a fluorine element; a is an integer of 1 to 3; b is an integer of 0 to 2; and the sum of a and b is 3 or smaller, 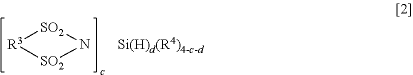
where R³ is each independently a C₁-C₈ divalent hydrocarbon group in which a part or all of hydrogen elements may be substituted with a fluorine element; R⁴ is each independently a C₁-C₁₈ monovalent hydrocarbon group in which a part or all of hydrogen elements may be substituted with a fluorine element; c is an integer of 1 to 3; d is an integer of 0 to 2; and the sum of c and d is 3 or smaller,
(R⁵—S(═O)₂)₃CₑSi(H)_{f}(R⁶)_{4-e-f} [3]
where R⁵ is each independently a group selected from the group consisting of a C₁-C₈ monovalent hydrocarbon group in which a part or all of hydrogen elements may be substituted with a fluorine element, and a fluorine element; R⁶ is each independently a C₁-C₁₈ monovalent hydrocarbon group in which a part or all of hydrogen elements may be substituted with a fluorine element; e is an integer of 1 to 3; f is an integer of 0 to 2; and the sum of e and f is 3 or smaller.

2. The water-repellent protective film forming agent according to claim 1, wherein, in the general formula [1], a is 1 and b is 0.

3. The water-repellent protective film forming agent according to claim 1, wherein, in the general formula [2], c is 1 and d is 0.

4. The water-repellent protective film forming agent according to claim 1, wherein, in the general formula [3], e is 1 and f is 0.

5. The water-repellent protective film forming agent according to claim 2, wherein at least two of R² in the general formula [1] are methyl.

6. The water-repellent protective film forming agent according to claim 3, wherein at least two of R⁴ in the general formula [2] are methyl.

7. The water-repellent protective film forming agent according to claim 4, wherein at least two of R⁶ in the general formula [3] are methyl.

8. A water-repellent protective film forming liquid chemical comprising: an organic solvent; and the water-repellent protective film forming agent according to claim 1 being dissolved in the organic solvent.

9. The water-repellent protective film forming liquid chemical according to claim 8, wherein the concentration of the water-repellent protective film forming agent is 0.01 to 25 mass % based on 100 mass % of the total amount of the water-repellent protective film forming agent and the organic solvent.

10. The water-repellent protective film forming liquid chemical according to claim 8, wherein the organic solvent is an aprotic solvent.

11. The water-repellent protective film forming liquid chemical according to claim 8, wherein the total amount of water contained in the water-repellent protective film forming agent and the organic solvent before preparation of the water-repellent protective film forming liquid chemical is 5000 mass ppm or less relative to the total amount of the water-repellent protective film forming agent and the organic solvent.

12. A method for cleaning a silicon element-containing surface of a wafer with the use of the water-repellent protective film forming agent or water repellent protective film forming liquid chemical according to according to claim 1.

13. A cleaning method for cleaning a silicon element-containing surface of a wafer with the use of the water-repellent protective film forming liquid chemical according to claim 8.
